(19) United States
(12) Patent Application Publication
(10) Pub. No.: US 2025/0070071 A1
(43) Pub. Date: Feb. 27, 2025

(54) SEMICONDUCTOR DEVICE AND SEMICONDUCTOR DEVICE FABRICATION METHOD

(71) Applicant: LAPIS Technology Co., Ltd., Yokohama-shi (JP)

(72) Inventor: Daisuke TAKAGI, Yokohama-shi (JP)

(73) Assignee: LAPIS Technology Co., Ltd., Yokohama-shi (JP)

(21) Appl. No.: 18/810,723

(22) Filed: Aug. 21, 2024

(30) Foreign Application Priority Data
Aug. 23, 2023 (JP) 2023-135456

(51) Int. Cl. H01L 23/00; H01L 21/56; H01L 23/31; H01L 23/495; H01L 25/065

(52) U.S. Cl. CPC H01L 24/16; H01L 21/565; H01L 23/3107; H01L 23/49541; H01L 24/02; H01L 24/81; H01L 25/0655; H01L 2224/02381; H01L 2224/16245; H01L 2224/81815; H01L 2924/35121

(57) ABSTRACT

A semiconductor device including: a semiconductor chip including redistribution wiring; a lead frame including a die pad mounted with the semiconductor chip and a lead connected to the die pad, wherein the redistribution wiring and the die pad are electrically connected by a solder or a conductive adhesive; and a sealing member that seals the semiconductor chip.

### CROSS-REFERENCE TO RELATED APPLICATION

This application claims priority under 35 USC 119 from Japanese Patent Application No. 2023-135456, filed on Aug. 23, 2023, the disclosure of which is incorporated by reference herein.

### BACKGROUND

### Technical Field

Technology disclosed herein relates to a semiconductor device and a semiconductor device fabrication method.

### Related Art

The following technology is known as technology related to semiconductor devices. A semiconductor device described in Japanese Patent Application Laid-Open (JP-A) No. 2013-232544, includes an oscillator mounted to a first face of a lead frame, and includes an integrated circuit mounted to a second face of the lead frame, with the oscillator and the integrated circuit connected to the lead frame by bonding wires.

A semiconductor device described in JP-A No. 2011-60805, includes a semiconductor element, at least one electrode portion disposed on one face of the semiconductor element, an insulating layer formed so as to cover the one face of the semiconductor element except at the electrode portion, wiring provided on the insulating layer, and an external terminal formed on the wiring.

A surface mounted semiconductor package, such as a small outline package (SOP) or a quad flat package (QFP), includes a semiconductor chip, a lead frame, and a sealing member. The lead frame includes a die pad and leads. The semiconductor chip is mounted on the lead frame, and the semiconductor chip and the leads are connected together through bonding wires. Bonding wires are difficult to employ to connect the semiconductor chip, and the leads together in such a surface mounted package, and the size of the package becomes significantly bigger than the size of the semiconductor chip. Moreover, there is a possibility that an inductance component arising from the bonding wires might affect electrical characteristics. There is also a risk of breakage or peeling off of the bonding wires.

A chip sized package (CSP) is known as a package to eliminate the above. A CSP is a semiconductor package that does not include bonding wires, with the package size being substantially the same as the size of the semiconductor chip itself. A concern with a CSP is reliability due to the semiconductor chip being exposed, and handling of CSPs is also not easy.

### SUMMARY

A first aspect of the present disclosure is a semiconductor device including: a semiconductor chip including redistribution wiring; a lead frame including a die pad mounted with the semiconductor chip and a lead connected to the die pad, wherein the redistribution wiring and the die pad are electrically connected by a solder or a conductive adhesive; and a sealing member that seals the semiconductor chip.

A second aspect of the present disclosure is a semiconductor device fabrication method including: preparing a semiconductor chip including redistribution wiring; connecting, for a lead frame including a die pad and a lead connected to the die pad, the die pad and the redistribution wiring together using a solder or a conductive adhesive; and sealing the semiconductor chip using a sealing member.

### BRIEF DESCRIPTION OF THE DRAWINGS

Exemplary embodiment will be described in detail based on the following figures, wherein:

FIG. 1 is a perspective view illustrating an example of a configuration of a semiconductor device;

FIG. 2 is a cross-sectional view taken along line 2-2 in FIG. 1;

FIG. 3 is a plan view illustrating an example of a configuration of a lead frame according to an exemplary embodiment;

FIG. 4 is a cross-section illustrating an example of a configuration of a semiconductor chip according to an exemplary embodiment;

FIG. 5A to FIG. 5H are cross-sectional views illustrating an example of a method of fabricating a semiconductor device according to an exemplary embodiment;

FIG. 6 is a cross-sectional view comparing sizes of a semiconductor device according to an exemplary embodiment to a surface mounted semiconductor device according to a comparative example; and

FIG. 7A to FIG. 7D are cross-sectional views illustrating examples of other configurations of semiconductor devices according to an exemplary embodiment.

### DETAILED DESCRIPTION

Technology disclosed herein enables provision of a semiconductor device and a semiconductor device fabrication method that are capable of achieving a size smaller than a conventional surface mounted package, and are capable of raising reliability more than a conventional CSP.

Description follows regarding an example of an exemplary embodiment of the present disclosure, with reference to the drawings. Note that the same reference numerals will be appended across the drawings to the same or equivalent configuration elements and parts, and duplicate explanation thereof will be omitted.

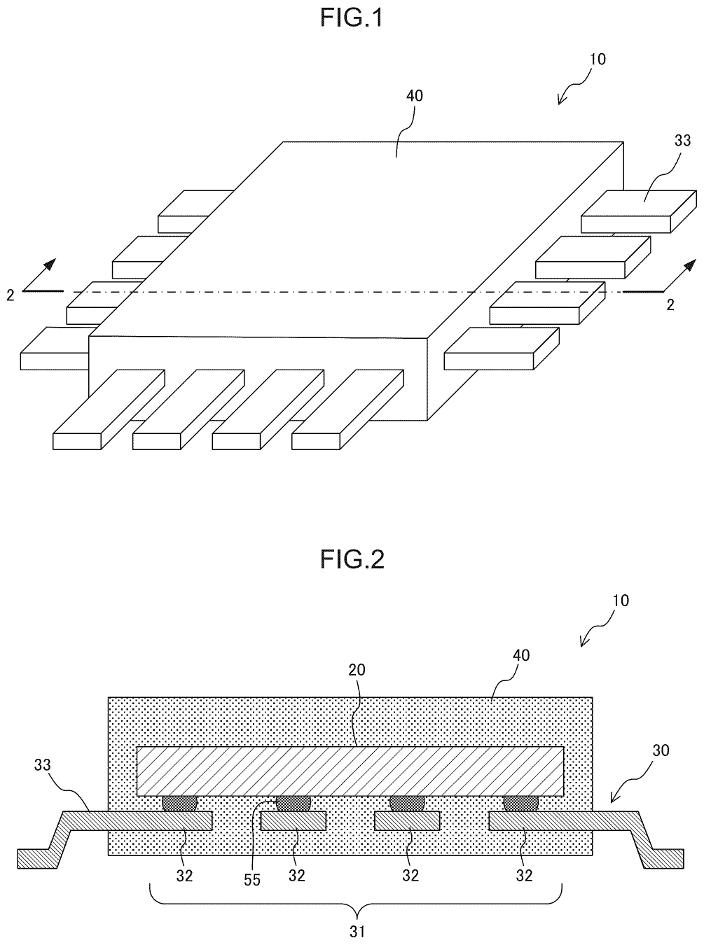

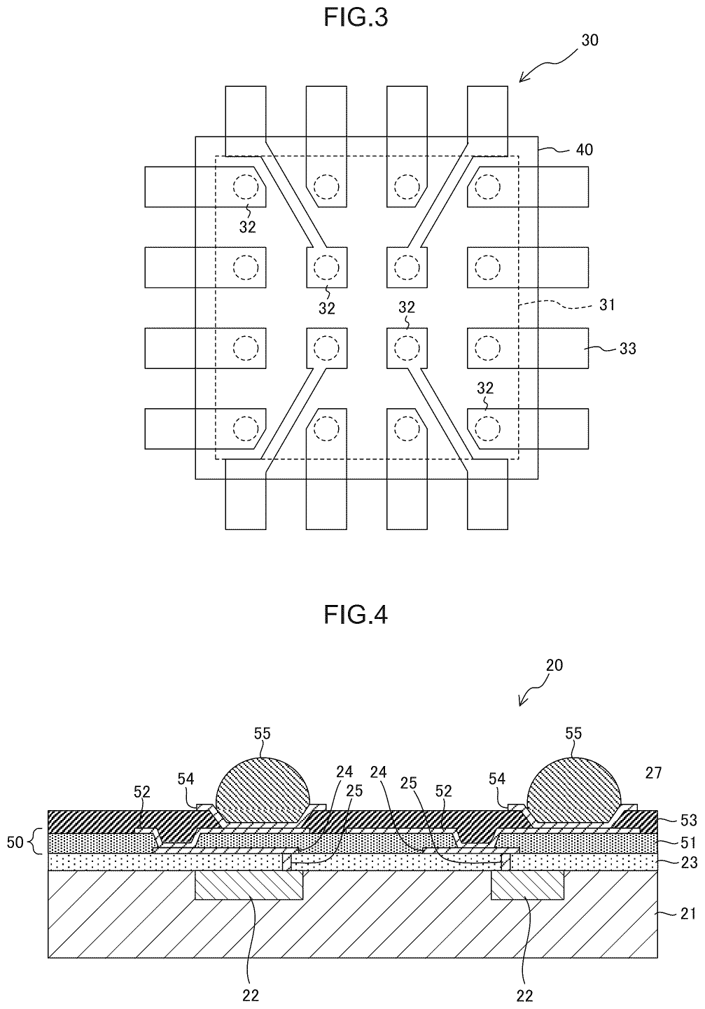

FIG. 1 is a perspective view illustrating an example of a configuration of a semiconductor device 10 according to an exemplary embodiment of technology disclosed herein. FIG. 2 is a cross-sectional view taken along line 2-2 in FIG. 1. The semiconductor device 10 includes a semiconductor chip 20, a lead frame 30, and a sealing member 40. FIG. 3 is a plan view illustrating an example of a configuration of the lead frame 30. FIG. 4 is a cross-sectional view illustrating an example of a configuration of the semiconductor chip 20.

As illustrated in FIG. 4, the semiconductor chip 20 includes a semiconductor substrate 21 formed with circuit elements 22, an insulating film 23 that covers the semiconductor substrate 21, and electrodes 24 provided on the insulating film 23 and connected to the circuit elements 22. The semiconductor substrate 21 is, for example, a silicon substrate. The circuit elements 22 are each, for example, a transistor, a diode, a resistance element, or a capacitor. The insulating film 23 is, for example, configured by an insulator such as SiO₂. The electrodes 24 are connected to the circuit elements 22 through vias 25 that penetrate through the insulating film 23. The vias 25 and the electrodes 24 are, for example, configured from a conductor, such as Al or the like.

The semiconductor chip 20 includes a redistribution layer 50 provided on the insulating film 23. The redistribution layer 50 has a size the same as the plan view size of the semiconductor substrate 21. The redistribution layer 50 includes an insulating film 51 configured from an insulator, such as a polyimide or polybenzoxazole (PBO), and redistribution wiring 52 provided on the surface of the insulating film 51. The redistribution wiring 52 is connected to the electrodes 24 exposed at opening portions formed in the insulating film 51. The redistribution wiring 52 is, for example, configured from a conductor, such as Cu or the like.

The surface of the redistribution layer 50 is covered by an insulating film 53 configured from an insulator, for example a photosensitive resin or the like. Terminal pads 54 are connected to the redistribution wiring 52 exposed through opening portions formed in the insulating film 53. Plural connection terminals 55 are provided on the surface of the terminal pads 54. The connection terminals 55 may have a solder ball form. The redistribution wiring 52 and the terminal pads 54 are, for example, configured from a conductor, such as Cu or the like.

The semiconductor chip 20 is a ball grid array (BGA) type chip component having a CSP form and including the redistribution layer 50 with a size the same as the plan view size of the semiconductor substrate 21.

As illustrated in FIG. 2, the semiconductor chip 20 is mounted to the lead frame 30. The lead frame 30 is produced by taking a thin plate having excellent electrically conductivity/mechanical strength/heat conductivity/corrosion resistance, such as a copper alloy-based material or an iron alloy-based material, and progressively performing precision press processing (punching, drawing, bending) thereon. The lead frame 30 includes a die pad 31 mounted with the semiconductor chip 20, and leads 33 connected to the die pad 31. In FIG. 3, an area illustrated by a rectangular broken line is an area of the die pad 31, which is the semiconductor chip 20 mounting area.

The die pad 31 includes plural separated pieces 32 that are electrically isolated from each other, and that respectively correspond to each of plural connection terminals 55 of the semiconductor chip 20. Each of the plural connection terminals 55 is connected to a corresponding separated piece 32 from out of the plural separated pieces 32. In FIG. 3 portions connected to the connection terminals 55 are indicated by circular broken lines. The connection terminals 55 are configured by solder balls. Namely, the redistribution wiring 52 of the semiconductor chip 20 is electrically connected by solder to the die pad 31 of the lead frame 30. Bonding wires are not employed to electrically connect the semiconductor chip 20 and the lead frame 30 in the semiconductor device 10 according to the present exemplary embodiment. Note that a form not configured by solder balls may be applied for the connection terminals 55. In such cases, for example, connection between the redistribution wiring 52 and the die pad 31 may be performed using a solder paste or a conductive adhesive supplied onto the die pad 31.

The sealing member 40 seals the die pad 31 and the semiconductor chip 20. Namely, the die pad 31 and the semiconductor chip 20 are embedded inside the sealing member 40. The sealing member 40 is configured by a thermosetting epoxy resin. The leads 33 respectively connected to the separated pieces 32 of the die pad 31 extend to outside the sealing member 40.

The semiconductor device 10 according to the present exemplary embodiment has a QFP form with the leads 33 arranged along each of the four edges of the rectangular shaped scaling member 40. As illustrated in FIG. 3, the leads 33 are formed in a desired shape.

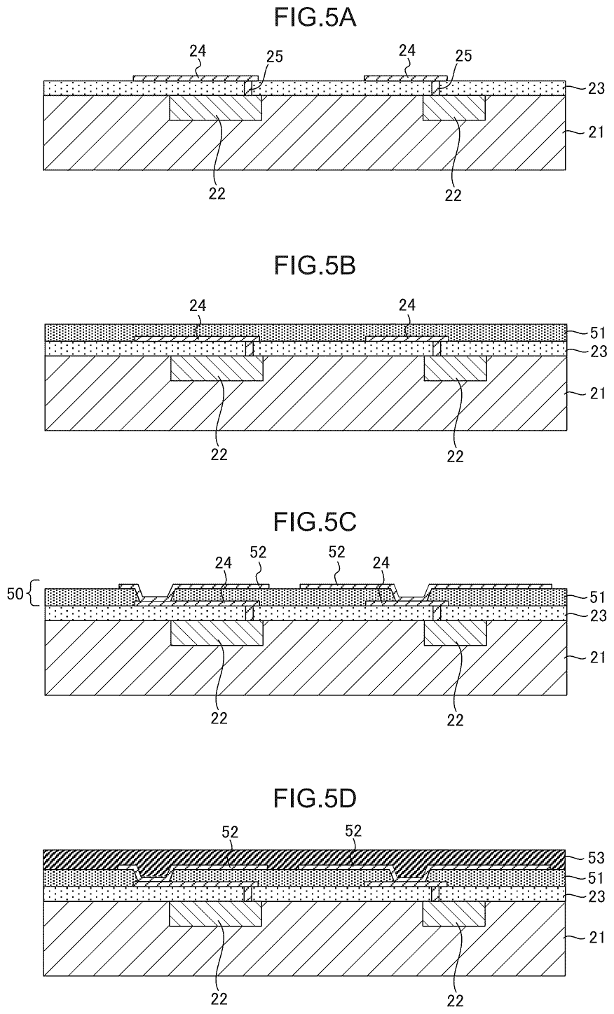

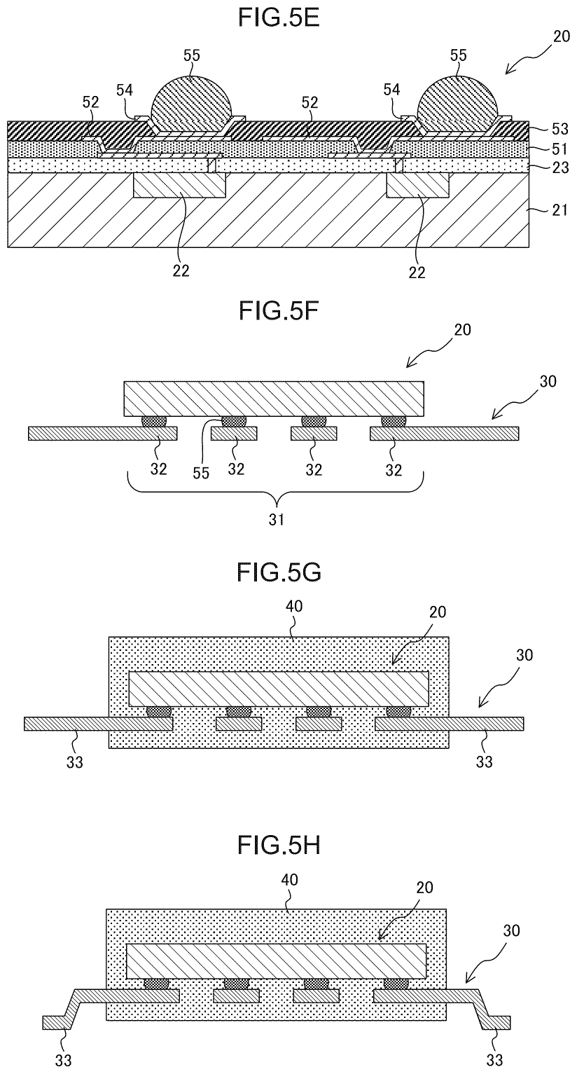

Explanation follows regarding a method of fabricating the semiconductor device 10, with reference to FIG. 5A to FIG. 5H. First, a known semiconductor fabrication process is employed to form the circuit elements 22, such as transistors, diodes, resistance elements, or capacitors, on the semiconductor substrate 21 (FIG. 5A). Then, a chemical vapor deposition (CVD) method is employed to form the insulating film 23 configured by an insulator such as SiO₂ on the circuit forming surface of the semiconductor substrate 21 (FIG. 5A). Then, photolithographic technology is employed to form contact holes through the insulating film 23 at specific positions thereof. Then, a sputter method is employed to form a conductor film configured from a conductor such as Al or the like on the surface of the insulating film 23. The contact holes formed in the insulating film 23 are thereby filled with the conductor, forming through vias 25 connected to the circuit elements 22. Then, the electrodes 24 connected to the vias 25 are formed by patterning the conductor film using photolithographic technology (FIG. 5A).

Next, a resin such as polyimide, PBO, or the like is coated onto the insulating film 23, after which this resin is cured to form the insulating film 51 (FIG. 5B).

Next, opening portions are formed in the insulating film 51 using photolithographic technology. The electrodes 24 are exposed through the opening portions. Next, a conductor film configured from a conductor, such as Cu or the like, is formed covering the surface of the insulating film 51 by using an electroplating method. Then, the conductor film is patterned using photolithographic technology. The redistribution wiring 52 connected to the electrodes 24 is formed thereby (FIG. 5C). The plan view size of the redistribution layer 50 configured by the insulating film 51 and the redistribution wiring 52 is the same as the plan view size of the semiconductor substrate 21.

Next, a photosensitive resin is coated on the surface of the insulating film 51, and after this the insulating film 53 is formed by curing this photosensitive resin (FIG. 5D).

Next, opening portions are formed in the insulating film 53 using photolithographic technology. The redistribution wiring 52 is partially exposed at the opening portions. Next, a conductor film configured from a conductor, such as Cu or the like, is formed covering the surface of the insulating film 53 using an electroplating method. Then, the terminal pads 54 are formed connected to the redistribution wiring 52 by patterning the conductor film using photolithographic technology (FIG. 5E). Next, the connection terminals 55 configured from solder balls are formed on the terminal pads 54 (FIG. 5E). The semiconductor chip 20 is produced through performing each of the processes described above.

Next, the semiconductor chip 20 is mounted to the die pad 31 of the lead frame 30, and reflow processing is performed (FIG. 5F). The semiconductor chip 20 and the lead frame 30 are thereby connected together by the solder balls configuring the connection terminals 55. Namely, the semiconductor chip 20 is connected to the lead frame 30 in a flip-chip connection state. Each of the plural respective connection terminals 55 of the semiconductor chip 20 is connected to its corresponding separated piece 32 from out of the plural separated pieces 32 of the die pad 31. The redistribution wiring 52 provided on the semiconductor chip 20 is electrically connected to the separated pieces 32 of the die pad 31 and to the leads.

Next, the die pad 31 and the semiconductor chip 20 are sealed by the sealing member 40 (FIG. 5G). The sealing member 40 is, for example, transfer molded. Transfer molding is a sealing method in which the lead frame mounted with a semiconductor chip is set in a molding mold, molten resin is filled into the mold cavity, and then cured. The die pad 31 and the semiconductor chip 20 are embedded inside the sealing member 40. The leads 33 connected to each of the separated pieces 32 of the die pad 31 extend outside the scaling member 40 (FIG. 5H).

As described above, the semiconductor device 10 according to the present exemplary embodiment includes the semiconductor chip 20 that includes the redistribution wiring 52, the lead frame 30 that includes the die pad 31 mounted with the semiconductor chip 20 and the leads 33 connected to the die pad 31, with the redistribution wiring 52 and the die pad 31 electrically connected by solder or conductive adhesive, and the sealing member that seals the semiconductor chip 20.

The semiconductor chip 20 includes the semiconductor substrate 21 formed with the circuit elements 22, the insulating film 23 covering the semiconductor substrate 21, the electrodes 24 provided on the insulating film 23 and connected to the circuit elements 22 and also connected to the redistribution wiring 52, and the connection terminals 55 connected to the redistribution wiring 52. The redistribution wiring 52 is provided in the redistribution layer 50 that has the same size as the plan view size of the semiconductor substrate 21.

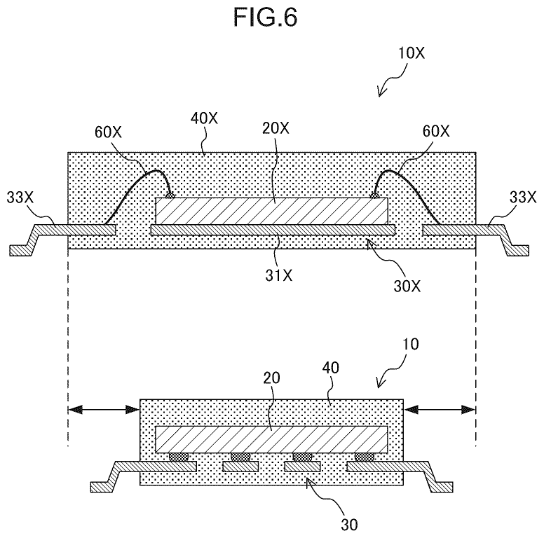

FIG. 6 is a cross-sectional view comparing sizes between the semiconductor device 10 according to the present exemplary embodiment and a surface mounted semiconductor device 10X according to a comparative example.

The semiconductor device 10X according to the comparative example includes a semiconductor chip 20X, a lead frame 30X, and a sealing member 40X. The lead frame 30X includes a die pad 31X and leads 33X. The semiconductor chip 20X is mounted on the lead frame 30X, with the semiconductor chip 20X and the leads 33X connected together through bonding wires 60X. In such a surface mounted package, the size of the package is significantly larger than the size of the semiconductor chip 20X due to employing the bonding wires 60X to connect the semiconductor chip 20X and the leads 33X together. Moreover, there is a concern that an inductance component arising from the bonding wires 60X might affect electrical characteristics. There is also a risk of breakage or peeling off of the bonding wires 60X.

CSPs are known as packages to eliminate the above issues. A CSP is a semiconductor package that does not include bonding wires, with a package size that is substantially the same as the size of the semiconductor chip itself. Issues with CSPs are a concern regarding reliability with a CSP due to the semiconductor chip being exposed, and that handling CSPs is also not easy.

On the other hand, the semiconductor device 10 according to an exemplary embodiment of technology disclosed herein does not employ bonding wires to connect the semiconductor chip 20 and the lead frame 30 together, and so as illustrated in FIG. 6. This enables the package size to be significantly smaller than the semiconductor device 10X according to the comparative example. Moreover, there is no inductance component formed by bonding wires. Furthermore, a risk of breakage or peeling off of bonding wires may be avoided.

Moreover, although the semiconductor chip 20 according to the present exemplary embodiment has a CSP form, the semiconductor chip 20 is sealed by the sealing member 40, and so the issues regarding reliability and handling of conventional CSPs may be eliminated.

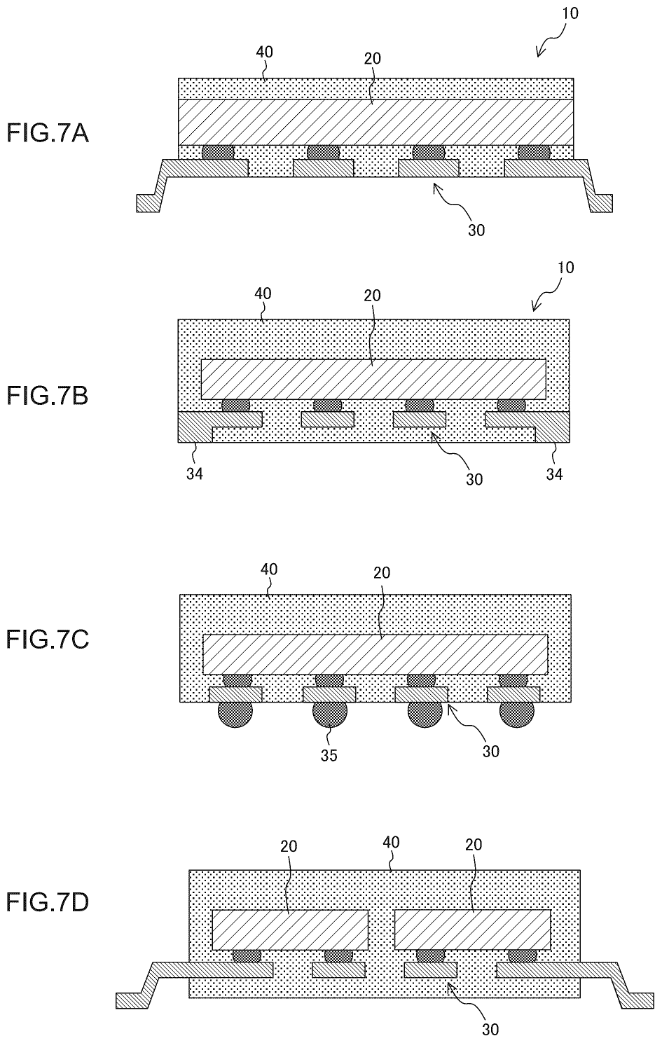

Various modifications may be made to the configuration of the semiconductor device 10. FIG. 7A to FIG. 7D are respectively cross-sectional views illustrating examples of other configurations of the semiconductor device 10. As illustrated in FIG. 7A, side faces of the semiconductor chip 20 may be exposed from the sealing member 40. This enables the amount of resin, which is the material employed for the sealing member 40, to be suppressed, while still securing reliability.

Moreover, as illustrated in FIG. 7B, the semiconductor device 10 may have a quad flat non-leaded package (QFN) form. In a QFN, electrode pads 34 are employed as terminals for connection instead of leads. Adopting a QFN for the package form enables the package size to be smaller than in a QFP.

Moreover, as illustrated in FIG. 7C, the semiconductor device 10 may have a BGA form. In a BGA, instead of leads, solder balls 35 are arrayed in a lattice shape on the back face of the package. Adopting a BGA for the package form enables the package size to be smaller than in a QFP.

Moreover, as illustrated in FIG. 7D, the semiconductor device 10 may include plural semiconductor chips 20. Such plural semiconductor chips 20 are each mounted to the lead frame 30 and sealed by the sealing member 40.

The following supplements are also disclosed in relation to the above exemplary embodiments.

### Supplement 1

A semiconductor device including:
a semiconductor chip including redistribution wiring;
a lead frame including a die pad mounted with the semiconductor chip and a lead connected to the die pad, wherein the redistribution wiring and the die pad are electrically connected by a solder or a conductive adhesive; and
a sealing member that seals the semiconductor chip.

### Supplement 2

The semiconductor device of Supplement 1, wherein the semiconductor chip includes;
a semiconductor substrate formed with a circuit element;
an insulating film that covers the semiconductor substrate;
an electrode provided on the insulating film, the electrode connected to the circuit element and to the redistribution wiring; and
a connection terminal connected to the redistribution wiring,
wherein the redistribution wiring is provided in a redistribution layer having a size the same as a plan view size of the semiconductor substrate.

### Supplement 3

The semiconductor device of Supplement 1 or Supplement 2, wherein:
the semiconductor chip includes plural connection terminals connected to the redistribution wiring;
the die pad includes plural separated pieces electrically isolated from each other and respectively corresponding to each of the plural connection terminals; and
each of the plural connection terminals is connected to a corresponding separated piece from out of the plural separated pieces.

### Supplement 4

The semiconductor device of any one of Supplement 1 to Supplement 3, a side face of the semiconductor chip is exposed from the sealing member.

### Supplement 5

The semiconductor device of any one of Supplement 1 to Supplement 4, wherein:
plural semiconductor chips are mounted to the lead frame; and
the sealing member seals the plural semiconductor chips.

### Supplement 6

A semiconductor device fabrication method including:
preparing a semiconductor chip including redistribution wiring;
connecting, for a lead frame including a die pad and a lead connected to the die pad, the die pad and the redistribution wiring together using a solder or a conductive adhesive; and
sealing the semiconductor chip using a sealing member.

What is claimed is:

1. A semiconductor device comprising:
a semiconductor chip including redistribution wiring;
a lead frame including a die pad mounted with the semiconductor chip and a lead connected to the die pad, wherein the redistribution wiring and the die pad are electrically connected by a solder or a conductive adhesive; and
a sealing member that seals the semiconductor chip.

2. The semiconductor device of claim 1, wherein the semiconductor chip includes:
a semiconductor substrate formed with a circuit element;
an insulating film that covers the semiconductor substrate;
an electrode provided on the insulating film, the electrode connected to the circuit element and to the redistribution wiring; and
a connection terminal connected to the redistribution wiring,
wherein the redistribution wiring is provided in a redistribution layer having a size the same as a plan view size of the semiconductor substrate.

3. The semiconductor device of claim 1, wherein:
the semiconductor chip includes a plurality of the connection terminals connected to the redistribution wiring;
the die pad includes a plurality of separated pieces electrically isolated from each other and respectively corresponding to each of the plurality of connection terminals; and
each of the plurality of connection terminals is connected to a corresponding separated piece from out of the plurality of separated pieces.

4. The semiconductor device of claim 1, wherein a side face of the semiconductor chip is exposed from the sealing member.

5. The semiconductor device of claim 1, wherein:
a plurality of the semiconductor chips are mounted to the lead frame; and
the sealing member seals the plurality of the semiconductor chips.

6. A semiconductor device fabrication method comprising:
preparing a semiconductor chip including redistribution wiring;
connecting, for a lead frame including a die pad and a lead connected to the die pad, the die pad and the redistribution wiring together using a solder or a conductive adhesive; and
sealing the semiconductor chip using a sealing member.

7. The semiconductor fabrication method of claim 6, wherein the semiconductor chip includes:
a semiconductor substrate formed with a circuit element;
an insulating film that covers the semiconductor substrate;
an electrode provided on the insulating film, the electrode connected to the circuit element and to the redistribution wiring; and
a connection terminal connected to the redistribution wiring.

8. The semiconductor fabrication method of claim 7, wherein the redistribution wiring is provided in a redistribution layer having a size the same as a plan view size of the semiconductor substrate.

9. The semiconductor fabrication method of claim 6, wherein:
the semiconductor chip includes a plurality of the connection terminals connected to the redistribution wiring;
the die pad includes a plurality of separated pieces electrically isolated from each other and respectively corresponding to each of the plurality of connection terminals; and
each of the plurality of connection terminals is connected to a corresponding separated piece from out of the plurality of separated pieces.

10. The semiconductor fabrication method of claim 6, wherein a side face of the semiconductor chip is exposed from the sealing member.
